(19) United States
(12) Patent Application Publication
(10) Pub. No.: US 2026/0032935 A1
(43) Pub. Date: Jan. 29, 2026

(54) ASYMMETRIC DEEP-TRENCH-MIM-CAPACITOR (ADTMC)

(71) Applicant: Applied Materials, Inc., Santa Clara, CA (US)

(72) Inventor: Seann William AYERS, Phoenix, AZ (US)

(73) Assignee: Applied Materials, Inc., Santa Clara, CA (US)

(21) Appl. No.: 18/786,175

(22) Filed: Jul. 26, 2024

(51) Int. Cl. H10D 1/68

(52) U.S. Cl. CPC H10D 1/716

(57) ABSTRACT

A semiconductor device may include a substrate may include one or more hexagonal trenches extending into the substrate from a first side of the substrate. The device may include one or more deep trench capacitors (DTCs), each formed in a respective hexagonal trench. Each DTC may include a liner layer, formed within the respective hexagonal trench and in contact with the substrate. The DTC may include a first conductor layer including a first metal, the first conductor layer formed within the respective hexagonal trench and in contact with the liner layer. The DTC may include a dielectric layer including a dielectric material, the dielectric layer formed within the respective hexagonal trench and in contact with the first conductor layer. The DTC may include a second conductor layer including a second metal, the second conductor layer formed within the respective hexagonal trench and in contact with the dielectric layer.

### TECHNICAL FIELD

The present technology relates to semiconductor systems, processes, and equipment. More specifically, the present technology relates to deep trench capacitors.

### BACKGROUND

A semiconductor device may require capacitors to provide consistent power delivery to various components of the semiconductor device. As these devices have grown more complex, the power requirements for the device has increased. Providing high capacitance while conserving space within the device itself may therefore be desired.

### BRIEF SUMMARY

A semiconductor device may include a substrate may include one or more hexagonal trenches extending into the substrate from a first side of the substrate. The semiconductor device may include one or more deep trench capacitors (DTCs), each formed in a respective hexagonal trench of the one or more hexagonal trenches. Each respective DTC may include a liner layer, formed within the respective hexagonal trench and in contact with the substrate. The respective DTC may include a first conductor layer including a first metal, the first conductor layer formed within the respective hexagonal trench and in contact with the liner layer. The respective DTC may include a dielectric layer including a dielectric material, the dielectric layer formed within the respective hexagonal trench and in contact with the first conductor layer. The respective DTC may include a second conductor layer including a second metal, the second conductor layer formed within the respective hexagonal trench and in contact with the dielectric layer.

In some embodiments, each respective DTC may include a second dielectric layer including the dielectric material, the dielectric layer formed within the respective hexagonal trench and in contact with the second conductor layer. Each respective DTC may include a third conductor layer including the first metal, the third conductor layer formed within the respective hexagonal trench and in contact with the second dielectric layer. Each respective DTC may include a third dielectric layer including the dielectric material, the dielectric layer formed within the respective hexagonal trench and in contact with the third conductor layer. Each respective DTC may include a fourth conductor layer including the second metal, the fourth conductor layer formed within the respective hexagonal trench and in contact with the third dielectric layer.

In some embodiments, the first conductor layer, the dielectric layer, and the second conductor layer may be circular. The one or more hexagonal trenches may be formed to a depth within a range of 2 μm to 10 μm, inclusive. Each respective DTC may include a capacitance within a range of 10 nf to 5 μf, inclusive. The device layer may be in contact with at least one of the respective DTCs. The one or more DTCs may be a component of a power delivery network.

A method of manufacturing a semiconductor device may include forming a trench within a substrate, a trench extending into the substrate from a first side of the substrate. The method may include forming a liner layer within the trench. The method may include forming a first conductive layer within the trench and in contact with the liner layer. The method may include forming a dielectric layer within the trench and in contact with the first conductive layer. The method may include forming a second conductive layer within the trench and in contact with the dielectric layer. The method may include connecting at least one of the first conductive layer or the second conductive layer to a power delivery network such that the first conductive layer, the dielectric layer, and the second conductive layer forms a deep trench capacitor (DTC).

In some embodiments, the first conductive layer and the second conductive layer may be formed from titanium nitride. The dielectric layer may be formed from aluminum oxide. The liner layer may be formed from silicon oxide. The liner layer may electrically insulate the DTC. The method may include forming an array of DTCs on the semiconductor device.

A semiconductor device (device) may include a substrate may include a trench. The device may include an insulator layer, formed within the trench. The device may include a first conductive layer, formed on the insulator layer. The device may include a dielectric layer, formed on the first conductive layer. The device may include a second conductive layer, formed on the dielectric layer.

In some embodiments, the trench may be hexagonal, pentagonal, or octagonal. The first conductive layer, the dielectric layer, and the second conductive layer may form concentric circles within the trench. The trench may be formed using at least one of ablation, drilling, or etching. The first conductive layer may be formed using at least one of electroplating, chemical vapor deposition, or sputtering. The dielectric layer may be formed using at least one of electroplating, chemical vapor deposition, or sputtering. The second conductive layer may be formed using at least one of electroplating, chemical vapor deposition, or sputtering.

### BRIEF DESCRIPTION OF THE DRAWINGS

FIG. 1 shows a top plan view of one embodiment of a processing system of deposition, etching, baking, and/or curing chambers, according to certain embodiments.

FIG. 2 shows a schematic cross-sectional view of an exemplary plasma system according to certain embodiments.

FIG. 3 illustrates a flowchart of a method for forming an asymmetrical deep trench capacitor, according to certain embodiments.

FIGS. 4A-4F illustrate a semiconductor device with an asymmetrical deep trench capacitor, according to certain embodiments.

FIGS. 5A-B illustrate a top-down view of an asymmetrical deep trench capacitor, according to certain embodiments.

### DETAILED DESCRIPTION

As semiconductor structures (e.g., an advanced package) and devices continue to evolve, the demand for capacitance density increase, sometimes dramatically. Increased capacitance density is critical for meeting stringent power integrity requirements of current and future semiconductor structures and devices. Conventional power distribution networks (PDNs) attempt to maximize the capacitive density of a given area of the package. To achieve this, the PDN may include a deep-trench-capacitor(s) (DTC) to provide capacitance density with minimal unwanted inductance, resistance/inductance parasitic, and/or other unwanted effects.

Generally, DTCs of a PDN within an advanced package may be rectangular, arranged in a line or lines to provide the necessary capacitance for the PDN. The total capacitance of available to the PDN is therefore proportional to the total number of DTCs manufactured in the package. Each DTCs may be built from a single, symmetrical trench with a positive terminal and negative terminal separated by a dielectric layer. Standard cell size of a DTC (e.g., a planar cross section of the trench/DTC) may be approximately 40 μm by 40 μm. This means that each square millimeter may include 625 cells. Commonly, each DTC may have a capacitance of about 544 pF per cell, meaning that the package may have a captiance density of about 340 nF per mm². While this capacitance density may perform under certain conditions, improvements in capacitance density are desired to provide more consistent power to modern advanced packages and other semiconductor devices.

One solution may be to incorporate asymmetrical DTCs into semiconductor devices. A hexagonal trench may be created in a substrate of the semiconductor device (e.g., an advanced package). The hexagonal shape of the trench may enable a greater density of DTCs to be arranged within the package. Then, a liner layer may be deposited within the hexagonal trench. The liner layer may insulate the DTC from other elements within the package. The liner layer may also be formed such that an interior surface of the liner layer may be circular, decahedral, octagonal, etc. Then, alternating metal layers and dielectric layers may be deposited within the liner layer. The metal layers may form the positive and negative terminals of the asymmetrical DTC, separated by dielectric layers. A back end of line (BEOL) process may then connect the positive terminals and the negative terminals to a PDN and/or device layer of the advanced package. A resulting cross section of the asymmetrical DTC may then have a hexagonal outer boundary and concentric rings (e.g., circular, octagonal, etc.). Because the surface area of a given cross section increases as the cross section approaches circular (i.e., the surface area of a circle of a given perimeter is greater than the that of a rectangle with the same perimeter), the asymmetrical DTC may result in a higher capacitance density as compared to standard DTCs. The alternating layers may further increase the capacitance density.

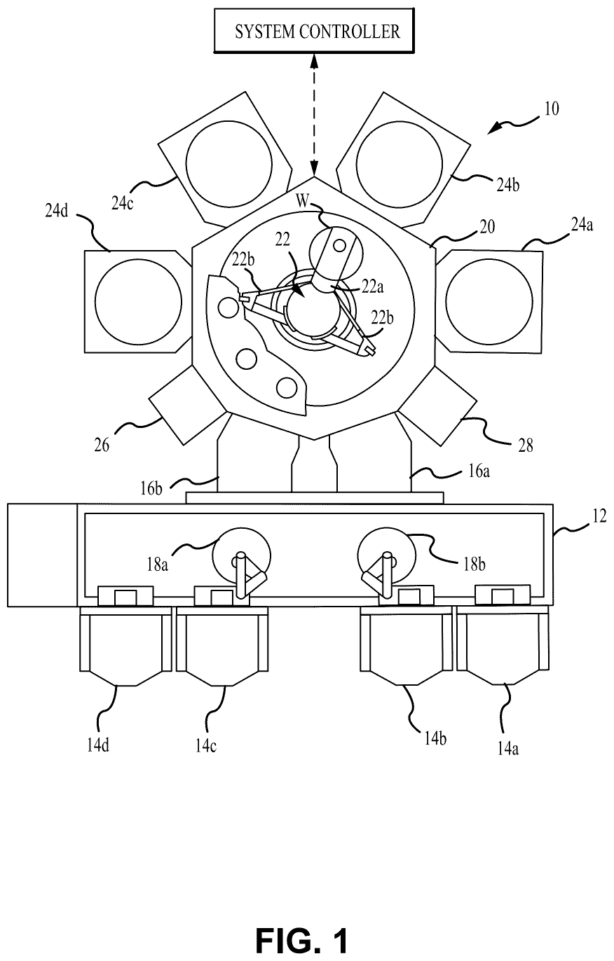

FIG. 1 shows a top plan view of one embodiment of a processing system 10 of deposition, etching, baking, and/or curing chambers according to certain embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 25b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

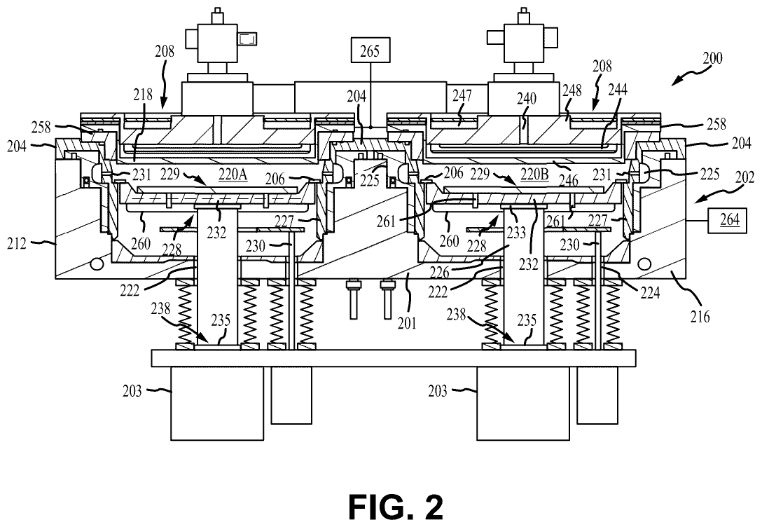

FIG. 2 shows a schematic cross-sectional view of an exemplary plasma system 200 according to certain embodiments. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

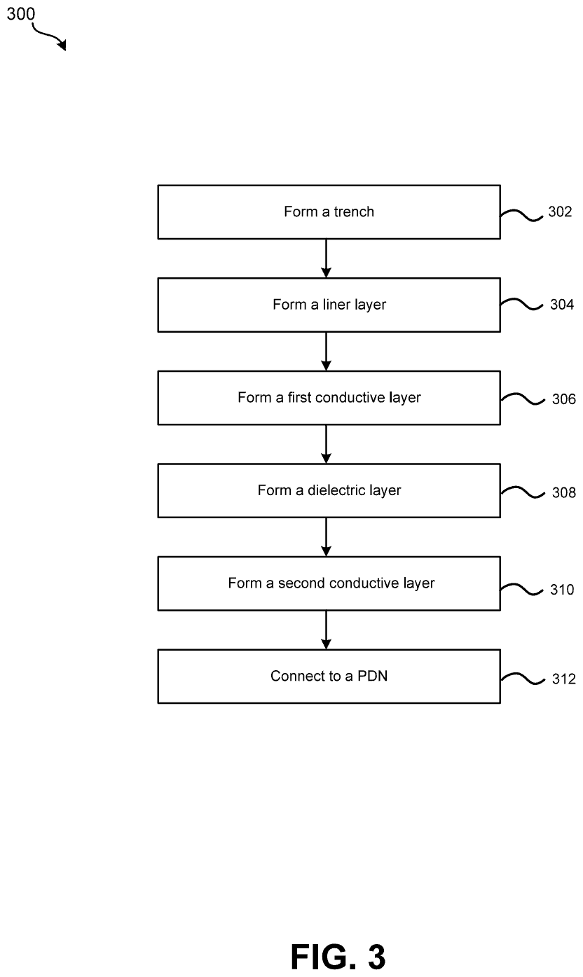

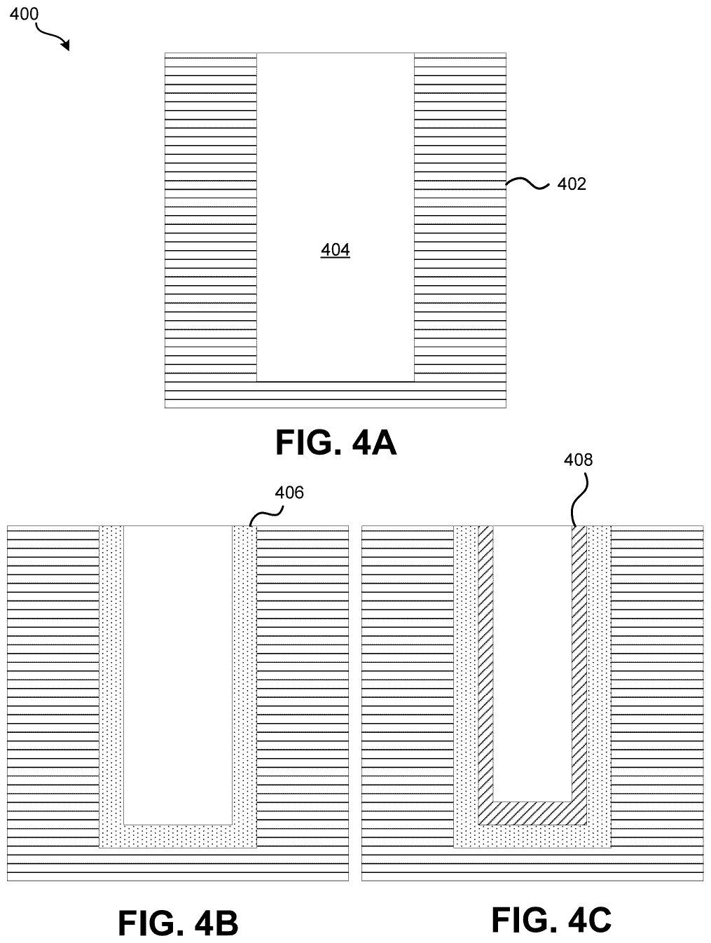

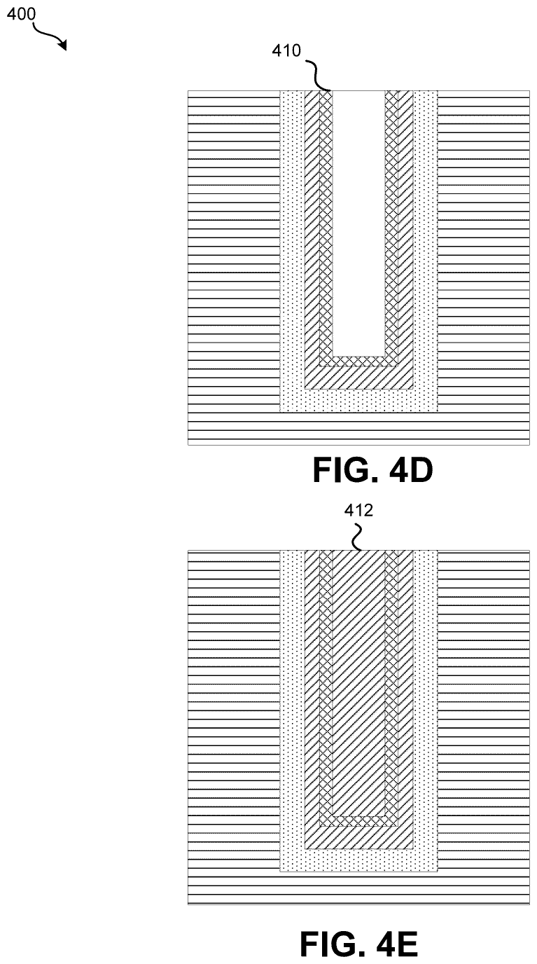

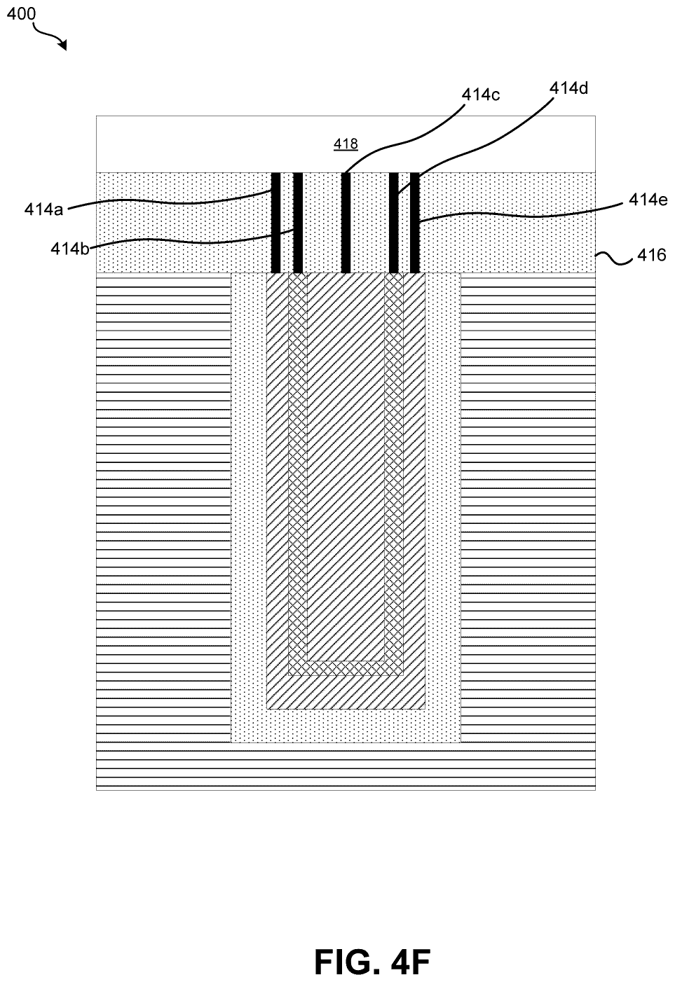

FIG. 3 illustrates a flowchart of a method 300 for forming an asymmetrical deep trench capacitor, according to certain embodiments. The method 300 may be performed using the chamber(s) discussed previously. The method 300 may include one or more operations prior to the initiation of the method, including front end processing, deposition, etching, polishing, cleaning, back end of line (BEOL) processing, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. The method 300 may describe a semiconductor device 400, shown schematically in FIGS. 4A-4F, the illustration of which will be described in conjunction with the operations of method 300. It is to be understood that the figures illustrate only partial schematic views, and a substrate may contain any number of additional materials and features having a variety of characteristics and aspects as illustrated in the figures.

At step 302, the method 300 may include forming a trench 404 within a substrate 402, the trench 404 extending into the substrate 402 from a first side of the substrate, as shown in FIG. 4A. The substrate 402 may include a silicon, gallium, indium, antimonide, carbide, phosphorous, nitrogen, and/or and other suitable material and/or any combination thereof. The substrate 402 may be used to form the semiconductor device 400 (e.g., an advanced package, system on a chip, etc.). Thus, the substrate 402 may be formed in order to provide capacitance for a device layer (to be formed and/or attached later).

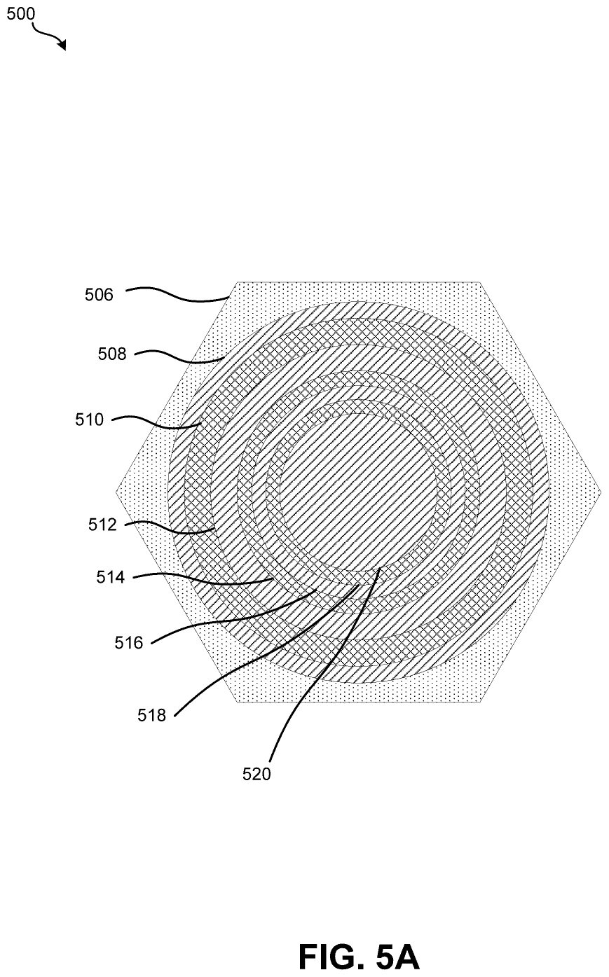

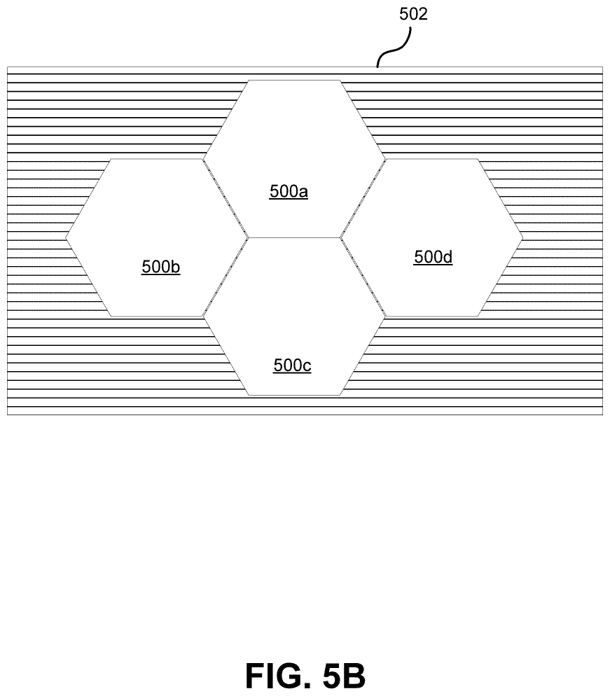

Although FIG. 4A shows the trench 404 as rectangular, it should be understood that top-down cross section of the trench 404 may be hexagonal (as shown subsequently in FIG. 5), pentagonal, octagonal, or any other such shape. The trench 404 may be formed by a drilling process, an ablation process, a chemical etching process, and/or any combination of these processes. For example, the trench 404 may be etched and subsequently shaped via drilling or otherwise removing material from the trench 404. Thus, the shape of the trench 404 may be created after the etching process.

The trench 404 may have a diameter of 1 μm (as measured from opposite corners of a hexagon). Alternatively, the trench may have a diameter of about 0.5 μm, about 1.5 μm, about 2 μm, or about 3 μm. The trench 404 may have a depth (extending into the substrate) of about 6.5 μm. Alternatively, the trench 404 may have a depth of about 4 μm, about 4.5 μm, about 5 μm, about 5.5 μm, about 6.5 μm, about 7 μm, or greater than about 8 μm. In some embodiments, the substrate may have multiple trenches. Then, the trenches may all be identical or have differeing dimensions.

At step 304, the method 300 may include forming a liner layer 406 within the trench 404 as shown in FIG. 4B. The liner layer 406 may be formed using a deposition process (e.g., chemical vapor deposition), electroplating, sputtering or any other suitable technique. The liner layer 406 may include silicon oxide and/or any other suitable material. The liner layer 406 may insulate the DTC (to be formed within the trench 404 via the method 300) from other elements of the semiconductor device 400. The liner layer 406 may include a thickness of about 10 nm to about 500 nm, inclusive. An inner surface of the liner layer 406 may have a different shape than an outer surface of the liner layer 406. For example, the outer surface of the liner layer (i.e., the surface in contact with the substrate within the trench 404) may be generally hexagonal. The inner surface may be generally circular, octagonal, decahedral, or any other suitable shape.

At step 306, the method 300 may include forming a first conductive layer 408 within the trench 404 and in contact with the liner layer 406, as shown in FIG. 4C. The first conductive layer 408 may be formed using a deposition process (e.g., chemical vapor deposition), electroplating, sputtering or any other suitable technique. The first conductive layer 408 may include copper, titanium, nitrogen, titanium nitride, tungsten, any other suitable metal, and/or any combination thereof. The first conductive layer 408 may include a thickness of about 10 nm to about 500 nm, inclusive. The first conductive layer 408 may have a shape generally corresponding to that of the inner surface of the liner layer 406. For example, if the inner surface of the liner layer is generally circular, the first conductive layer 408 may also be generally circular.

At step 308, the method 300 may include forming a dielectric layer 410 within the trench 404 and in contact with the first conductive layer 408, as shown in FIG. 4D. The dielectric layer 410 may using a deposition process (e.g., chemical vapor deposition), electroplating, sputtering or any other suitable technique. The dielectric layer 410 may include aluminum oxide, ceramic, mica, glass, and/or any other suitable material. The material used in the dielectric layer 410 may include a lower dielectric constant than that of the liner layer 406, allowing charge to flow through the dielectric layer 410 before the liner layer 406. The dielectric layer 410 may be formed to include a thickness of about 10 nm to about 500 nm, inclusive, and include a shape generally conforming to that of the first conductive layer 408.

At step 310, the method 300 may include forming a second conductive layer 412 within the trench 404 and in contact with the dielectric layer 410, as shown in FIG. 4E. The second conductive layer 412 may be formed using a deposition process (e.g., chemical vapor deposition), electroplating, sputtering or any other suitable technique. The second conductive layer 412 may include copper, titanium, nitrogen, titanium nitride, tungsten, any other suitable metal, and/or any combination thereof. The second conductive layer 412 may include a thickness of about 10 nm to about 500 nm, inclusive. The second conductive layer 412 may have a shape generally corresponding to that of the dielectric layer 410.

As shown in FIGS. 4A-4E, the DTC of the semiconductor device 400 may include two terminals (i.e., the first and second conductive layer) and one dielectric layers. However, the DTC may include any number of layers. For example, the DTC may include 4 conductive layers and 3 dielectric layers, 5 conductive layers and 4 dielectric layers, etc. In other words, the asymmetrical DTC shown in FIGS. 4A-4E may be configured to have any number of capacitors within the trench 404. The semiconductor device 400 may therefore be configured to provide any level of capacitance desired.

At step 312, the method 300 may include connecting at least one of the first conductive layer 408 or the second conductive layer 412 to a PDN such that the first conductive layer 408, the dielectric layer 410, and the second conductive layer 412 forms the DTC. As shown in FIG. 4F, connections 414a-e may connect the various layers of the DTC to a device layer 418. The connections 414a-e may include copper, silver, gold, tungsten, and/or any other suitable conductor. The connections 414a-e may be formed in a BEOL process. The connections 414a-e may connect to one or more devices in the device layer 418 and/or may connect to a PDN. For example, the connections 414a, 414c, and 414e may connect to devices within the device layer 418. The connections 414b and 414d may connect to the PDN of the semiconductor device 400. Then, as power is delivered to the DTC via the connections 414b and 414d, the DTC may then provide power to the devices in the device layer 418 via the connections 414a, 414c, and 414e.

FIG. 5A illustrates a top-down view of an asymmetrical deep trench capacitor 500, according to certain embodiments. The DTC 500 may be similar to the DTC formed via the method 300 and illustrated in FIGS. 4A-4F. Thus, the DTC 500 may be formed in a substrate of a semiconductor device such as an advanced package, system on a chip, or other such device. The DTC 500 may include a liner layer 506, a first conductive layer 508, a first dielectric layer 510, a second conductive layer 512, a second dielectric layer 514, a third conductive layer 516, a third dielectric layer 518, and a fourth conductive layer 520. The liner layer 506 may be similar to the liner layer 406 in FIGS. 4A-4F. Thus, the liner layer 506 may be an insulator layer and include silicon oxide and/or any other suitable material.

The first conductive layer 508, the second conductive layer 512, the third conductive layer 516, and the fourth conductive layer 520 (collectively “conductive layers”) may cach be similar to the first and/or second conductive layers 408 and 412. Thus, the conductive layers 508-520 may include copper, titanium, nitrogen, titanium nitride, tungsten, any other suitable metal, and/or any combination thereof. The conductive layers 508-520 may each act as a terminal of the DTC 500, forming metal-insulator-metal (MIM) capacitors. For example, the first and third conductive layers 508 and 516 may be positive terminals (e.g., connected to a PDN of the semiconductor device) and the second and thirds conductive layers 512 and 520 may be negative terminals (e.g., connected to the device layer of the semiconductor device). One of ordinary skill in the art would recognize many different possibilities.

As shown in FIG. 5A, the outer shape of the top-down cross section of the DTC 500 may be hexagonal. The hexagonal shape may provide manufacturing efficiencies and allow more DTCs to be placed in an area (e.g., more efficient tessellation). The conductive layers 508-520 and the dielectric layers 510-518 may have a different shape, however. Thus, the DTC 500 may be an asymmetrical DTC, where the shapes of the components are not necessarily the same. As shown in FIG. 5A, the shapes of the conductive layers 508-520 and the dielectric layers 510-518 are generally circular. In other embodiments, some or all of the conductive layers 508-520 and the dielectric layers 510-518 may be generally octagonal, generally decahedral, generally dodecagonal, etc. Capacitance is proportional to the surface area of the terminals of the capacitor. Greater surface area therefore results in a higher capacitance. Thus, as the shape of the conductive layers 508-520 and the dielectric layers 510-518 approaches circular, the more capacitance the DTC 500 may achieve. In some embodiments, the DTC 500 may have a capacitance of about 3.35 pF per MIM. As the DTC 500 includes 2 MIMs (alternating conductive and dielectric layers), the DTC 500 may include a capacitance of about 6.7 pF. In other embodiments, the DTC 500 may include a capacitance within a range of 2 pF to 10 pF, inclusive.

Turning to FIG. 5B, multiple DTCs 500a-d are shown arranged on a substrate 502. The hexagonal shape of the DTCs 500a-d illustrate one embodiment of how asymmetrical DTCs may be arranged. One of ordinary skill in the art would recognize many other possibilities and configurations. The hexagonal structure of the trenches (e.g., the trench 404, the DTCs 500a-d)) may maximized 2D tessellation on a surface area of the substrate 502 while the circular MIM structure of the DTC 500 maximizes device capacitance. For example, The array of the DTCs 500a-d may include a pitch of 1.25 μm. Then, a 30 by 30 MIM array (i.e., the DTCs 500a-d) may be included in a 40 μm by 40 μm cell. Thus, using the asymmetrical DTCs 500a-d (and 500), the total capacitance of the cell may be about 2 μF per mm ². By contrast, conventional DTC cells may have a capacitance of about 340 nF per mm ². In other words, the technology disclosed and described herein may result in a 6× capacitance increase over conventional DTCs.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a device layer” includes a plurality of such layers, and reference to “the first DTC” includes reference to one or more asymmetrical DTCs and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor device, comprising:
a substrate comprising one or more hexagonal trenches extending into the substrate from a first side of the substrate; and
one or more deep trench capacitors (DTCs), each formed in a respective hexagonal trench of the one or more hexagonal trenches, each respective DTC comprising:
a liner layer, formed within the respective hexagonal trench and in contact with the substrate;
a first conductor layer comprising a first metal, the first conductor layer formed within the respective hexagonal trench and in contact with the liner layer;
a dielectric layer comprising a dielectric material, the dielectric layer formed within the respective hexagonal trench and in contact with the first conductor layer; and
a second conductor layer comprising a second metal, the second conductor layer formed within the respective hexagonal trench and in contact with the dielectric layer.

2. The semiconductor device of claim 1, wherein each respective DTC further comprises:
a second dielectric layer comprising the dielectric material, the dielectric layer formed within the respective hexagonal trench and in contact with the second conductor layer;
a third conductor layer comprising the first metal, the third conductor layer formed within the respective hexagonal trench and in contact with the second dielectric layer;
a third dielectric layer comprising the dielectric material, the dielectric layer formed within the respective hexagonal trench and in contact with the third conductor layer; and
a fourth conductor layer comprising the second metal, the fourth conductor layer formed within the respective hexagonal trench and in contact with the third dielectric layer.

3. The semiconductor device of claim 1, wherein the first conductor layer, the dielectric layer, and the second conductor layer are circular.

4. The semiconductor device of claim 1, wherein the one or more hexagonal trenches are formed to a depth within a range of 2 μm to 10 μm, inclusive.

5. The semiconductor device of claim 1, wherein each respective DTC comprises a capacitance within a range of 10 nf to 5 μf, inclusive.

6. The semiconductor device of claim 1, further comprising a device layer, wherein the device layer is in contact with at least one of the respective DTCs.

7. The semiconductor device of claim 1, wherein the one or more DTCs are a component of a power delivery network.

8. A method of manufacturing a semiconductor device, the method comprising:
forming a trench within a substrate, a trench extending into the substrate from a first side of the substrate;
forming a liner layer within the trench;
forming a first conductive layer within the trench and in contact with the liner layer;
forming a dielectric layer within the trench and in contact with the first conductive layer;
forming a second conductive layer within the trench and in contact with the dielectric layer; and
connecting at least one of the first conductive layer or the second conductive layer to a power delivery network such that the first conductive layer, the dielectric layer, and the second conductive layer forms a deep trench capacitor (DTC).

9. The method of claim 8, wherein the first conductive layer and the second conductive layer is formed from titanium nitride.

10. The method of claim 8, wherein the dielectric layer is formed from aluminum oxide.

11. The method of claim 8, wherein the liner layer is formed from silicon oxide.

12. The method of claim 8, wherein the liner layer electrically insulates the DTC.

13. The method of claim 8, further comprising forming an array of DTCs on the semiconductor device.

14. A semiconductor device, comprising:
a substrate comprising a trench;
an insulator layer, formed within the trench;
a first conductive layer, formed on the insulator layer;
a dielectric layer, formed on the first conductive layer; and
a second conductive layer, formed on the dielectric layer.

15. The semiconductor device of claim 14, wherein the trench is hexagonal, pentagonal, or octagonal.

16. The semiconductor device of claim 15, wherein the first conductive layer, the dielectric layer, and the second conductive layer form concentric circles within the trench.

17. The semiconductor device of claim 14, wherein the trench is formed using at least one of ablation, drilling, or etching.

18. The semiconductor device of claim 14, wherein the first conductive layer is formed using at least one of electroplating, chemical vapor deposition, or sputtering.

19. The semiconductor device of claim 14, wherein the dielectric layer is formed using at least one of electroplating, chemical vapor deposition, or sputtering.

20. The semiconductor device of claim 14, wherein the second conductive layer is formed using at least one of electroplating, chemical vapor deposition, or sputtering.
